(19) United States
(12) Patent Application Publication
(10) Pub. No.: US 2026/0231688 A1
(43) Pub. Date: Aug. 6, 2026

(54) METHOD FOR MANUFACTURING SUPERCONDUCTING QUANTUM DEVICE

(71) Applicant: NEC Corporation, Tokyo (JP)

(72) Inventor: Shun YANAI, Tokyo (JP)

(73) Assignee: NEC Corporation, Tokyo (JP)

(21) Appl. No.: 19/445,759

(22) Filed: Jan. 12, 2026

(30) Foreign Application Priority Data
Feb. 3, 2025 (JP) 2025-015956

(51) Int. Cl. H10N 60/01

(52) U.S. Cl. CPC H10N 60/0156; H10N 60/0912

(57) ABSTRACT

A method for manufacturing a superconducting quantum device, the method includes forming an insulating film on a substrate, forming a protective film on the insulating film, performing etching from a back surface of the substrate using the protective film as a mask to form a thin-film region that is not supported by the substrate on the insulating film formed on a front surface of the substrate, removing the protective film after the thin-film region is formed, and forming a superconducting quantum circuit on the thin-film region.

### CROSS REFERENCE TO RELATED APPLICATIONS

This application is based upon and claims the benefit of priority from Japanese Patent Application No. 2025-015956, filed on February 3, 2025, the disclosure of which is incorporated herein in its entirety by reference.

### TECHNICAL FIELD

The present disclosure relates to a method for manufacturing a superconducting quantum device.

### BACKGROUND ART

JP H04-335515 A described below discloses an X-ray exposure mask including a silicon substrate held by a support, an X-ray transmissive film formed on the silicon substrate, and an X-ray absorption layer pattern formed on the X-ray transmissive film. In this mask, first, a film of silicon nitride, silicon carbide, or the like, which has a thickness of about 2 μm, is formed as a membrane on the silicon substrate having a thickness of 0.5 to 2 mm by using various CVD methods, followed by film formation by sputtering an X-ray absorber such as tungsten or a tungsten compound with a thickness of 0.5 to 1 μm. The pattern of the X-ray absorber is further formed. Thereafter, the silicon substrate is etched from the back surface with a KOH solution, and a glass support ring having a thickness of about 5 mm is bonded.

### SUMMARY

An object of the present disclosure is to provide a method for manufacturing a superconducting quantum device that solves the above problem.

In order to solve the above problem, this disclosure proposes the following means.

A method for manufacturing a superconducting quantum device according to the present disclosure includes: an insulating film forming step of forming an insulating film on a substrate; a protective film forming step of forming a protective film on the insulating film; a thin-film region forming step of performing etching from a back surface of the substrate using the protective film as a mask to form a thin-film region that is not supported by the substrate on the insulating film formed on a front surface of the substrate; a protective film removing step of removing the protective film after the thin-film region is formed; and a superconducting quantum circuit forming step of forming a superconducting quantum circuit on the thin-film region.

### BRIEF DESCRIPTION OF THE DRAWINGS

Exemplary features and advantages of the present disclosure will become apparent from the following detailed description when taken with the accompanying drawings in which:

FIG. 1 is a flowchart of a method for manufacturing a superconducting quantum device according to a minimum configuration example of the present disclosure;

FIG. 2 is a cross-sectional schematic diagram of a superconducting quantum device according to an example embodiment of the present disclosure;

FIGS. 3A and 3B are explanatory diagrams of a method for manufacturing a superconducting quantum device according to an example embodiment of the present disclosure;

FIGS. 4A and 4B are explanatory diagrams of the method for manufacturing a superconducting quantum device according to the example embodiment of the present disclosure;

FIGS. 5A and 5B are explanatory diagrams of the method for manufacturing a superconducting quantum device according to the example embodiment of the present disclosure; and

FIG. 6 is a flowchart of steps included in a superconducting quantum circuit forming step according to the example embodiment of the present disclosure.

### EXAMPLE EMBODIMENT

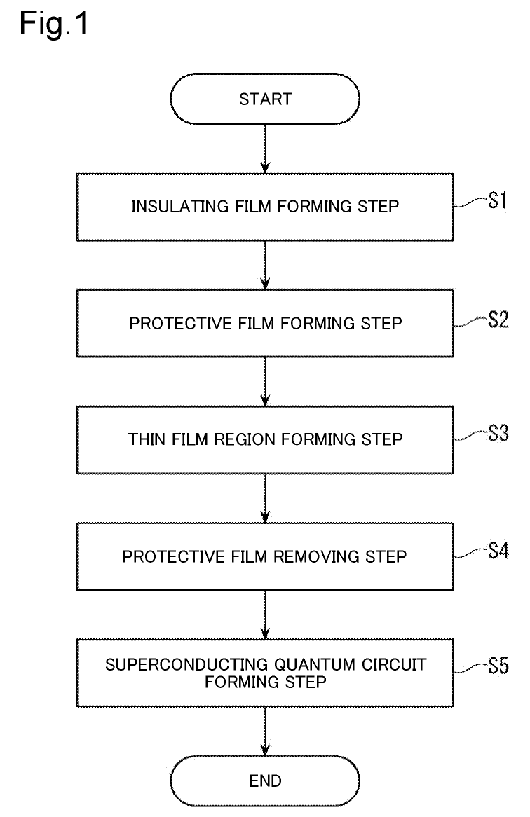

A minimum configuration example of the present disclosure will be described with reference to FIG. 1.

FIG. 1 is a flowchart of a method for manufacturing a superconducting quantum device according to a minimum configuration example of the present disclosure.

As illustrated in FIG. 1, the method for manufacturing a superconducting quantum device 1 of the present disclosure includes an insulating film forming step S1, a protective film forming step S2, a thin-film region forming step S3, a protective film removing step S4, and a superconducting quantum circuit forming step S5.

In the insulating film forming step S1, an insulating film is formed on a substrate. In the protective film forming step S2, a protective film (protective resist) is formed on the insulating film. In the thin-film region forming step S3, etching is performed from the back surface of the substrate using the protective film as a mask, and the thin-film region (membrane) that is not supported by the substrate is formed on the insulating film formed on the front surface of the substrate. In the protective film removing step S4, the protective film is removed after a thin-film region is formed. In the superconducting quantum circuit forming step S5, a superconducting quantum circuit is formed on the thin-film region.

In a case where a superconducting quantum circuit is formed in the thin-film region of the insulating layer in the order disclosed in JP H04-335515 A, first, a silicon nitride (SiN) film is formed on a silicon substrate by the low pressure chemical vapor deposition (LPCVD) method. Next, after the superconducting quantum circuit is formed on the SiN film, etching is performed from the back surface of the silicon substrate using silicon deep reactive ion etching (DRIE) and a potassium hydroxide (KOH) aqueous solution to form a thin-film region of the SiN film.

A challenge of the conventional technique is that the superconducting quantum circuit and KOH are not compatible with each other. When etching a bulk silicon substrate with KOH or the like from the back surface, it is necessary to apply a protective film in order to protect the superconducting quantum circuit from KOH or the like. This protective film contributes to the Q factor of a superconducting quantum circuit formed on the SiN film as a dielectric loss. That is, in a case where the superconducting quantum circuit is formed before the silicon substrate is etched from the back surface, the protective film cannot be removed by a strong acid. Therefore, a dielectric loss source remains on the front surface of the superconducting quantum device.

On the other hand, according to the present method illustrated in FIG. 1, after the etching of the back surface of the substrate (thin-film region forming step S3), the superconducting quantum circuit is formed on the thin-film region (membrane) of the insulating layer on the front surface of the substrate (superconducting quantum circuit forming step S5). As a result, the protective film removing step S4 is performed before the superconducting quantum circuit forming step S5, and the protective film serving as the dielectric loss source can be removed. Therefore, since the dielectric loss source remaining on the front surface of the superconducting quantum circuit can be reduced, the Q factor of the superconducting quantum device can be improved.

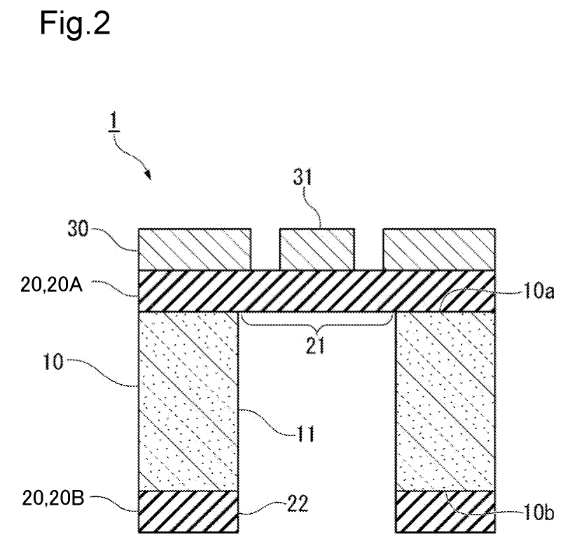

Next, an example embodiment of the present disclosure will be described with reference to FIGS. 2 to 6 in addition to FIG. 1.

FIG. 2 is a cross-sectional schematic diagram of the superconducting quantum device 1 according to the example embodiment of the present disclosure.

As illustrated in FIG. 2, the superconducting quantum device 1 includes a substrate 10, an insulating film 20, and a superconducting material film 30. On a front surface 10a of the substrate 10, the insulating film 20 (first insulating film 20A) and the superconducting material film 30 are laminated in this order. The insulating film 20 (second insulating film 20B) is laminated on the back surface 10b of the substrate 10.

The substrate 10 contains, for example, a semiconductor material such as a silicon (Si) substrate. The substrate 10 may contain, for example, an insulator material such as glass. The thickness of the substrate 10 is, for example, 10 μm to 500 μm (micrometers). The substrate 10 includes a front surface 10a, a back surface 10b opposite to the front surface 10a, and a through portion 11 extending from the back surface 10b to the front surface 10a.

The insulating film 20 contains, for example, an insulating material such as silicon nitride (SiN). The insulating film 20 may contain, for example, another insulator material such as silicon dioxide (SiO₂). The thickness of the insulating film 20 is, for example, 100 nm to 150 nm (nanometers). The insulating film 20 includes a first insulating film 20A covering the front surface 10a of the substrate 10 and a second insulating film 20B covering the back surface 10b of the substrate 10.

A thin-film region 21 (membrane) that is not supported by the substrate 10 is formed on the first insulating film 20A. The thin-film region 21 is formed on a portion facing an opening portion of the through portion 11. A communication hole communicating with the through portion 11 is formed on the second insulating film 20B. That is, in the through portion 11, the front surface 10a side of the substrate 10 is closed by the thin-film region 21, and the back surface 10b side of the substrate 10 is opened.

The superconducting material film 30 contains, for example, a superconducting material such as niobium (Nb).

The superconducting material film 30 may contain another superconducting material such as aluminum (Al) or titanium nitride (TiN). The thickness of the superconducting material film 30 is, for example, 0.1 μm to 0.5 μm (micrometers). A superconducting quantum circuit 31 is formed on the superconducting material film 30.

The superconducting quantum circuit 31 is, for example, configured as a transmission line-type superconducting resonator having a line length of 1/4 wavelength. The superconducting quantum circuit 31 may be a superconducting resonator in which a superconducting quantum interference device (SQUID) including a Josephson junction or the like is incorporated. The superconducting quantum circuit 31 is formed on the thin-film region 21 of the first insulating film 20A. According to this configuration, it is possible to minimize propagation of phonons to the substrate 10 upon collision with high-energy waves (such as gamma rays).

Next, a method for manufacturing the superconducting quantum device 1 having the above-described configuration will be described.

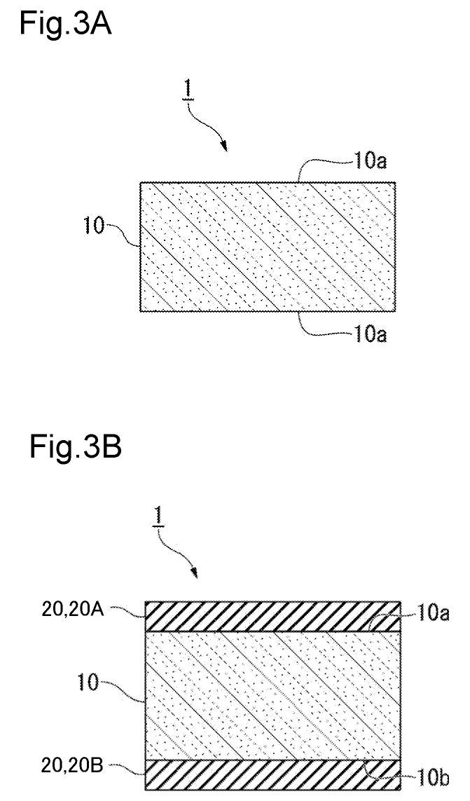

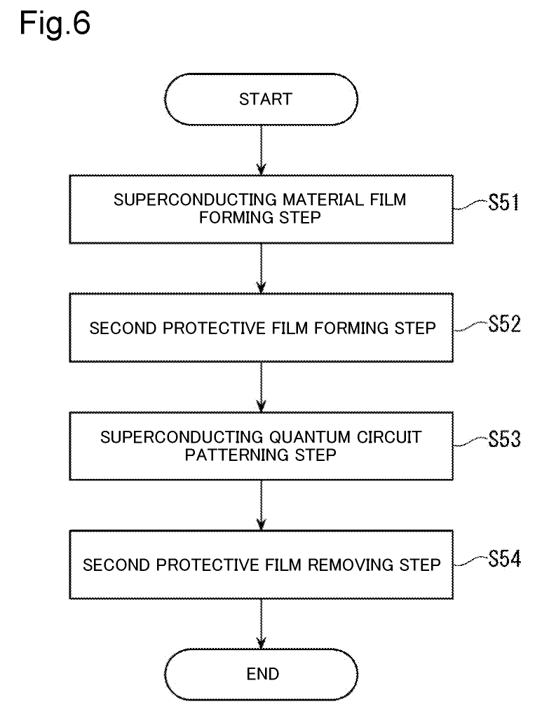

FIGS. 3A to 5B are explanatory diagrams of the method for manufacturing the superconducting quantum device 1 according to the example embodiment of the present disclosure. FIG. 6 is a flowchart of steps included in a superconducting quantum circuit forming step S5 according to the example embodiment of the present disclosure.

In this method, first, as illustrated in FIGS. 3A and 3B, the insulating film 20 is formed on the substrate 10. Specifically, the substrate 10 (silicon substrate) as illustrated in FIG. 3A is formed. Then, as illustrated in FIG. 3B, the insulating film 20 (SiN film) is formed to have a thickness of about 100 nm to 150 nm on the front surface 10a and the back surface 10b of the substrate 10 by low pressure chemical vapor deposition (LPCVD) method or the like.

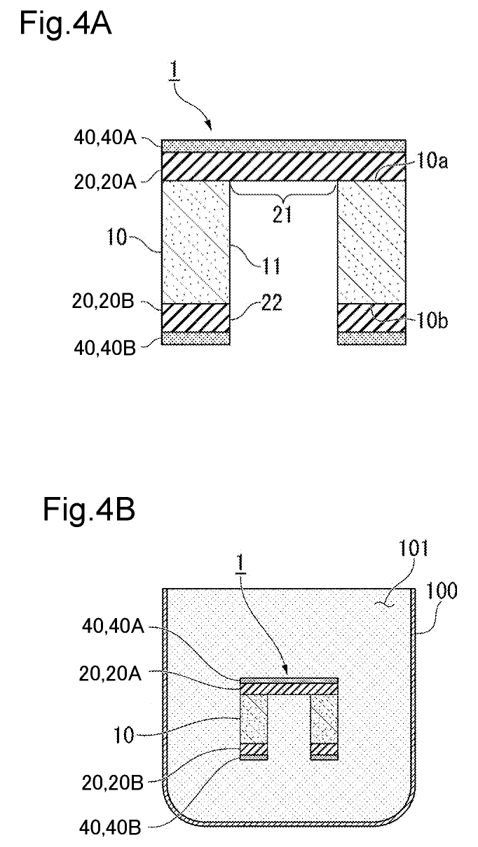

Next, in the present method, as illustrated in FIG. 4A, etching is performed from the back surface 10b of the substrate 10 using the protective film 40 as a mask, and the thin-film region 21 that is not supported by the substrate 10 is formed on the insulating film 20 formed on the front surface 10a of the substrate 10. Specifically, the first protective film 40A is formed on the first insulating film 20A, and a pattern for forming the through portion 11 is formed on the second protective film 40B on the second insulating film 20B by photolithography or the like.

As the protective film 40, a commercially available protective resist material can be used. As the protective film 40, for example, a resin including an acrylonitrile-styrene-based resin and an epoxy-based resin may be used, and as a primer, a resin composed of a silane coupling agent may be used. As the protective film 40, for example, a film made of an acrylic resin-based resist material such as methyl methacrylate may be used. In this case, since the polymer itself has good adhesion to metal and no primer such as a silane coupling agent is required, an issue that the primer remains on the device surface after removal of the resist with a cleaning liquid described later hardly occurs.

Next, by using the second protective film 40B as a mask, etching of the substrate 10 is performed from the back surface 10b of the substrate 10 using a potassium hydroxide (KOH) aqueous solution, DRIE (silicon deep reactive ion etching), or the like. As a result, the through portion 11 extending from the back surface 10b to the front surface 10a can be formed on the substrate 10, and the thin-film region 21 that is not supported by the substrate 10 can be formed on the first insulating film 20A. Tetramethylammonium hydroxide (TMAH) may be used instead of KOH.

Next, in the present method, as illustrated in FIG. 4B, the protective film 40 is removed in an acidic cleaning liquid 101 of a cleaning tank 100. This step includes cleaning a semiconductor manufacturing process using a normal acid, and performs, for example, RCA cleaning, piranha cleaning, BHF cleaning, and the like. By this cleaning, the protective film 40 resistant to KOH and TMAH can be removed, and it is possible to prevent the protective film from remaining as a dielectric loss source of the superconducting quantum circuit 31 described later.

In addition, organic substances other than the protective film 40 remaining on the surface of the insulating film 20 can also be removed by RCA cleaning, piranha cleaning, or the like.

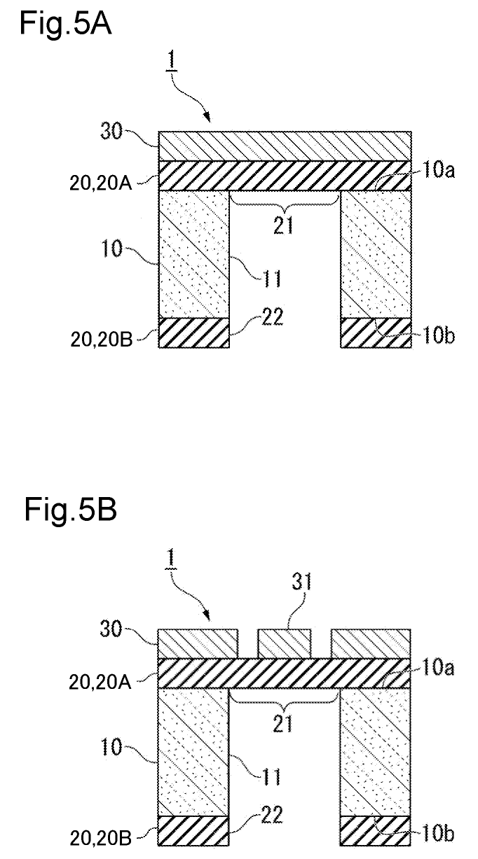

After the cleaning, in the present method, as illustrated in FIG. 5A, the superconducting material film 30 is formed on the first insulating film 20A. Then, the superconducting quantum circuit 31 is formed on the superconducting material film 30 by using normal photolithography. As described above, the superconducting quantum device 1 can be manufactured. As described above, according to the present method, since the protective film 40 serving as a dielectric loss source is removed before the superconducting quantum circuit forming step S5, the Q factor of the superconducting quantum device 1 can be improved.

As illustrated in FIG. 6, the superconducting quantum circuit forming step S5 includes a superconducting material film forming step S51, a second protective film forming step S52, a superconducting quantum circuit patterning step S53, and a second protective film removing step S54.

As illustrated in FIG. 5A, the superconducting material film forming step S51 is a step of forming the superconducting material film 30 on the thin-film region 21. The second protective film forming step S52 is a step of forming a second protective film (not illustrated) for forming the superconducting quantum circuit 31 on the superconducting material film 30. The superconducting quantum circuit patterning step S53 is a step of patterning the superconducting quantum circuit 31 on the superconducting material film 30 by reactive ion etching (RIE) or the like using the second protective film as a mask.

The second protective film removing step S54 is a step of removing the second protective film (mask). In the second protective film removing step S54, the second protective film may be removed with a cleaning liquid having a pH higher than that in the protective film removing step S4 (a cleaning liquid that is weaker in acidity than that used in the protective film removing step S4). As a result, it is possible to avoid causing damage to the superconducting quantum circuit 31.

In the present method, after back etching from the back surface 10b of the substrate 10, the superconducting quantum circuit 31 is patterned on the thin-film region 21 of the insulating film 20 on the front surface 10a of the substrate 10. Since the area of the thin-film region 21 is small, the deflection of the thin-film region 21 has almost no effect; however, in order to secure a large area for patterning the superconducting quantum circuit 31, a method for minimizing the deflection of the thin-film region 21 may be adopted.

The deflection of the thin-film region 21 may occur due to factors such as the center portion of the thin-film region 21 sagging downward under gravity, or compressive stress being applied as a result of the properties of the formed superconducting material film 30, which causes the thin-film region 21 to be deflected upward or downward. In order to eliminate these factors and reduce the deflection of the thin-film region 21, it is preferable to increase the magnitude of the tensile stress of the thin-film region 21.

Therefore, for example, in the protective film forming step S2 described above, the protective film 40 having a stoichiometric ratio of silicon and nitrogen of 3 : 4 may be formed by the chemical vapor deposition method. This is because the tensile stress of the SiN membrane is maximized when the SiN that is process deposited by LPCVD is in a stoichiometric Si3N4 ratio.

Furthermore, for example, in the superconducting quantum circuit forming step S5 described above, the superconducting material film 30 having a smaller compressive stress than that of the thin-film region 21 may be formed on the thin-film region 21. As a result, the compressive stress acting on the thin-film region 21 from the superconducting material film 30 can be reduced, and the deflection of the thin-film region 21 can be minimized.

As described above, a method for manufacturing the superconducting quantum device 1 of the present example embodiment includes: an insulating film forming step S1 of forming an insulating film 20 on a substrate 10; a protective film forming step S2 of forming a protective film 40 on the insulating film 20; a thin-film region forming step S3 of performing etching from a back surface 10b of the substrate 10 using the protective film 40 as a mask to form a thin-film region 21 that is not supported by the substrate 10 on the insulating film 20 formed on a front surface of the substrate 10; a protective film removing step S4 of removing the protective film 40 after the thin-film region 21 is formed; and a superconducting quantum circuit forming step S5 of forming a superconducting quantum circuit 31 on the thin-film region 21. According to this method, it is possible to improve the Q factor of the superconducting quantum device 1 including the superconducting quantum circuit 31 formed on the thin-film region 21 of the insulating film 20.

A superconducting quantum device including a superconducting resonator is used in a quantum computer or the like. Improvement of the internal Q factor of superconducting resonators is a major challenge not only in the field of quantum computing, but also in the field of astronomy and optomechanics.

In the related art, prototype superconducting resonators have been fabricated on insulating thin films, similar to the X-ray absorption layer pattern formed on an X-ray transmissive film as described in JP H04-335515 A, for the purpose of coupling with mechanical resonators. However, in applications related to quantum information, the microwave characteristics of prototype superconducting resonators fabricated on insulating thin films have received limited attention.

In recent years, studies have been conducted to reveal that one of the advantages of prototyping a superconducting resonator circuit on an insulating thin film such as silicon nitride (SiN) is the ability to prevent phonons from propagating into the bulk substrate upon collision with high-energy waves (such as gamma rays). However, the reported internal Q factor of the superconducting resonators is on the order of 10⁵, which is about one to two orders of magnitude lower than the Q factor of the superconducting resonators prototyped using state-of-the-art conventional methods.

According to the present disclosure, the Q factor of the superconducting quantum device including the superconducting quantum circuit formed on the thin-film region of the insulating film can be improved.

While the example embodiment of the present disclosure has been described above in detail with reference to the drawings, a specific configuration is not limited to the example embodiment and includes design change and the like within a range not departing from the gist of the present disclosure. And each example embodiment can be appropriately combined with other example embodiments.

A part or the entirety of the above-described example embodiment may also be described as the following Supplementary Notes, but is not limited to the following Supplementary Notes.

### Supplementary Note 1

A method for manufacturing a superconducting quantum device, the method including:

an insulating film forming step of forming an insulating film on a substrate;

a protective film forming step of forming a protective film on the insulating film;

a thin-film region forming step of performing etching from a back surface of the substrate using the protective film as a mask to form a thin-film region that is not supported by the substrate on the insulating film formed on a front surface of the substrate;

a protective film removing step of removing the protective film after the thin-film region is formed; and

a superconducting quantum circuit forming step of forming a superconducting quantum circuit on the thin-film region.

### Supplementary Note 2

The method for manufacturing a superconducting quantum device according to Supplementary Note 1, in which

in the protective film removing step, the protective film is removed with an acidic cleaning liquid.

### Supplementary Note 3

The method for manufacturing a superconducting quantum device according to Supplementary Note 1 or 2, in which

the substrate is a silicon substrate.

### Supplementary Note 4

The method for manufacturing a superconducting quantum device according to any one of Supplementary Notes 1 to 3, in which

the insulating film is silicon nitride.

### Supplementary Note 5

The method for manufacturing a superconducting quantum device according to any one of Supplementary Notes 1 to 4, in which

in the protective film forming step, the protective film having a stoichiometric ratio of silicon and nitrogen of 3 : 4 is formed by a chemical vapor deposition method.

### Supplementary Note 6

The method for manufacturing a superconducting quantum device according to any one of Supplementary Notes 1 to 5, in which

in the superconducting quantum circuit forming step, a superconducting material having a lower compressive stress than that of the thin-film region is deposited to form a film on the thin-film region.

### Supplementary Note 7

The method for manufacturing a superconducting quantum device according to any one of Supplementary Notes 1 to 6, in which

in the superconducting quantum circuit forming step, niobium serving as a superconducting material is deposited to form a film on the thin-film region.

### Supplementary Note 8

The method for manufacturing a superconducting quantum device according to any one of Supplementary Notes 1 to 7, in which

the superconducting quantum circuit forming step includes:

a superconducting material film forming step of forming a superconducting material film on the thin-film region;

a second protective film forming step of forming a second protective film on the superconducting material film;

a superconducting quantum circuit patterning step of patterning the superconducting quantum circuit on the superconducting material film using the second protective film as a mask.

### Supplementary Note 9

The method for manufacturing a superconducting quantum device according to Supplementary Note 8, in which

the superconducting quantum circuit forming step includes a second protective film removing step of removing the second protective film after the superconducting quantum circuit patterning step.

### Supplementary Note 10

The method for manufacturing a superconducting quantum device according to Supplementary Note 9, in which

in the second protective film removing step, the second protective film is removed with a cleaning liquid having a pH higher than that in the protective film removing step.

The previous description of embodiments is provided to enable a person skilled in the art to make and use the present disclosure. Moreover, various modifications to these example embodiments will be readily apparent to those skilled in the art, and the generic principles and specific examples defined herein may be applied to other embodiments without the use of inventive faculty. Therefore, the present disclosure is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

1. A method for manufacturing a superconducting quantum device, the method comprising:
forming an insulating film on a substrate;
forming a protective film on the insulating film;
performing etching from a back surface of the substrate using the protective film as a mask to form a thin-film region that is not supported by the substrate on the insulating film formed on a front surface of the substrate;
removing the protective film after the thin-film region is formed; and
forming a superconducting quantum circuit on the thin-film region.

2. The method for manufacturing a superconducting quantum device according to claim 1, wherein
the protective film is removed with an acidic cleaning liquid.

3. The method for manufacturing a superconducting quantum device according to claim 1, wherein
the substrate is a silicon substrate.

4. The method for manufacturing a superconducting quantum device according to claim 1, wherein
the insulating film is silicon nitride.

5. The method for manufacturing a superconducting quantum device according to claim 1, wherein
the protective film having a stoichiometric ratio of silicon and nitrogen of 3 : 4 is formed by a chemical vapor deposition method.

6. The method for manufacturing a superconducting quantum device according to claim 1, wherein
a superconducting material having a lower compressive stress than that of the thin-film region is deposited to form a film on the thin-film region.

7. The method for manufacturing a superconducting quantum device according to claim 1, wherein
niobium serving as a superconducting material is deposited to form a film on the thin-film region.

8. The method for manufacturing a superconducting quantum device according to claim 1, wherein forming the superconducting quantum circuit includes:
forming a superconducting material film on the thin-film region;
forming a second protective film on the superconducting material film; and
patterning the superconducting quantum circuit on the superconducting material film using the second protective film as a mask.

9. The method for manufacturing a superconducting quantum device according to claim 8, wherein
removing the second protective film after the superconducting quantum circuit is patterned.

10. The method for manufacturing a superconducting quantum device according to claim 9, wherein
the second protective film is removed with a cleaning liquid having a pH higher than that in the removing protective film.
